(19) United States
(12) Patent Application Publication
(10) Pub. No.: US 2018/0212072 A1
(43) Pub. Date: Jul. 26, 2018

(54) MANUFACTURING METHOD FOR SOLAR CELL AND SOLAR CELL

(71) Applicant: MITSUBISHI ELECTRIC CORPORATION, Chiyoda-ku, Tokyo (JP)

(72) Inventors: Yuichiro HOSOKAWA, Tokyo (JP); Hiroaki MORIKAWA, Tokyo (JP)

(73) Assignee: MITSUBISHI ELECTRIC CORPORATION, Chiyoda-ku, Tokyo (JP)

(21) Appl. No.: 15/745,322

(22) PCT Filed: Sep. 25, 2015
(86) PCT No.: PCT/JP2015/077168

§ 371 Date: Jan. 16, 2018

(51) Int. Cl. H01L 31/02; H01L 31/0224; H01L 31/18; C09D 11/037; C09D 11/52

(52) U.S. Cl. CPC H01L 31/0201; H01L 31/022433; H01L 31/02363; C09D 11/037; C09D 11/52; H01L 31/18

(57) ABSTRACT

In a manufacturing method for a solar cell, the solar cell includes: a solar cell substrate; and first and second collection electrodes formed on the solar cell substrate. At least one of the first and second collection electrodes includes: grid electrodes formed in a distributed manner over a whole surface of the solar cell substrate; and a bus electrode that is in contact with the grid electrodes and from which current is drawn. The method comprises forming a shape pattern of the bus electrode and the grid electrodes by performing a screen printing a plurality of times in such a manner that the bus electrode is divided in a longitudinal direction and that the divided bus electrodes include an overlapping region only in the longitudinal direction.

### FIELD

The present invention relates to a manufacturing method for a solar cell and to a solar cell, and particularly to the formation of an electrode.

### BACKGROUND

Typical conventional solar-cell substrate structures are obtained by providing an impurity diffusion layer having a different conductivity type on a silicon substrate to form a pn junction and by forming an electrode on the p-type region side and the n-type region side. For example, an n-type diffusion layer in which n-type impurities, such as phosphorus, are diffused to a depth ranging from 0.1 μm to 0.5 μm is provided on the main surface side of a p-type silicon substrate that is made of monocrystalline or polycrystalline silicon and has a thickness of about 0.20 mm. An antireflection and passivation film, which is a dielectric film made of, for example, Si₃N₄ or SiO₂, is then formed on the n-type diffusion layer in order to reduce the reflectivity of the light receiving surface, and bus electrodes and grid electrodes for drawing current are formed. Furthermore, a back surface field (BSF) layer in which p-type impurities, such as aluminum, are heavily diffused is formed on the back surface of the p-type silicon substrate, i.e., on the surface opposite the main surface of the p-type monocrystalline silicon substrate, and aluminum electrodes and back-surface bus electrodes are formed on the back surface.

This type of solar cell is typically manufactured using the printing and firing method described below. This is because, for example, with this method, grid electrodes or bus electrodes can be formed easily at low cost. In the printing and firing method, a conductive paste admixed with a high proportion of silver powder is used as the light-receiving-surface electrode material. After the conductive paste is applied by using a pattern forming method, such as a screen printing method, the conductive paste is sintered at high temperature in a firing furnace so as to form light-receiving-surface electrodes. In this electrode forming method, a conductive paste principally containing silver powder, glass frit, resin, and an organic solvent is generally used.

When the output of a finished solar cell is measured, probe pins for the measurement are brought into contact with the bus electrodes. Moreover, the bus electrodes are used for connecting thereto leads that are used for extracting, from the solar cell, carriers generated by the light that enters the solar cell.

Consequently, it is typically necessary for the bus electrodes to have a higher strength of adhesion to the cell than that of the grid electrodes, whereas the bus electrodes have a larger margin for the resistivity than the grid electrodes.

Because silver powder is an extremely expensive material, Patent Literature 1, for example, discloses a method of reducing the material cost. With this method, the bus electrodes and the grid electrodes are divided into two or more portions, and screen printing is performed two or more times in such a manner that the bus electrodes are formed to be thinner than the grid electrodes. Consequently, the amount of conductive paste used is reduced.

Moreover, Patent Literature 2 discloses a case in which an electrode paste material having a relatively high silver powder content is used for the grid electrodes or only the grid electrodes are formed by performing screen printing two or more times so that electrode pastes are stacked, thereby reducing the resistance of the grid electrodes. In Patent Literature 2, an electrode paste used for forming the bus electrodes has a lower silver powder content than that used for the grid electrodes or contains metal powder other than silver powder, such as copper powder, and the bus electrodes are formed by performing screen printing only once.

### CITATION LIST

### Patent Literature

Patent Literature 1: Japanese Utility Model Registration No. 3168227

Patent Literature 2: Japanese Utility Model Registration No. 3169353

### SUMMARY

### Technical Problem

With the conventional technologies described above, when divided electrode patterns are formed, it is however necessary to have overlapping portions in order to electrically connect the bus electrodes and the grid electrodes. Because the electrodes are formed such that the grid electrodes are superimposed on the bus electrodes, the electrodes have a large thickness only in the portions where the grid electrodes overlap with the bus electrodes and the bus electrodes thus have large irregularities. When a probe pin is lowered onto a bus electrode of such a solar cell in order to measure the output of the solar cell, the probe pin in some case partially comes into contact with a protruding portion of the bus electrode. Consequently, the contact resistance between the probe pin and the electrode changes, which may result in an incorrect measurement.

Moreover, when the probe pin has a sliding mechanism, because a force is not applied to the probe pin vertically in some cases, there is a problem in that degradation of the sliding portion is accelerated.

Furthermore, if leads known as tabbing wires are soldered to the protruding portions that are locally present on the bus electrodes, the adhesion strength is reduced.

To avoid these problems, it is possible to eliminate irregularities on the bus electrodes, for example, by forming overlapping regions by partially expanding the bus electrodes that are formed in the first printing to the grid electrode side and by forming the grid electrodes on the overlapping regions. In this case, however, it is necessary to ensure that the overlapping regions obtained by expanding the bus electrodes have an area that takes the positional accuracy of the screen printer into consideration. Applying such electrode patterns reduces, by the expanded area of the bus electrodes, the region through which light enters the solar cell to generate electrical power, which raises a problem in that the output decreases.

The present invention has been achieved in view of the above and an object of the present invention is to provide a solar cell that has excellent contact with measurement probes and excellent connectivity with tabbing wires in a case where grid electrodes and bus electrodes of the solar cell are formed by performing printing a plurality of times.

### Solution to Problem

In order to solve the above problems and achieve the object, in an aspect of the present invention, a solar cell includes: a solar cell substrate; and first and second collection electrodes formed on the solar cell substrate. At least one of the first and second collection electrodes includes: grid electrodes formed in a distributed manner over a whole surface of the solar cell substrate; and a bus electrode that is in contact with the grid electrodes and from which current is drawn. A shape pattern of the bus electrode and the grid electrodes is formed by performing a screen printing process a plurality of times in such a manner that the bus electrode is divided in a longitudinal direction and that the divided bus electrodes include an overlapping region only in the longitudinal direction.

### Advantageous Effects of Invention

According to the present invention, an effect is obtained where it is possible to obtain a solar cell that has excellent contact with measurement probes and excellent connectivity with tabbing wires in a case where grid electrodes and bus electrodes of the solar cell are formed by performing printing a plurality of times.

### BRIEF DESCRIPTION OF DRAWINGS

FIG. 1 is a top view schematically illustrating a light receiving surface of a solar cell according to a first embodiment.

FIG. 2 is a bottom view schematically illustrating a back surface of the solar cell according to the first embodiment.

FIG. 3 is a cross-sectional view taken along line A1-A1 in FIG. 1.

FIG. 4 is a cross-sectional view taken along line A2-A2 in FIG. 1.

FIG. 5 is an enlarged view of main parts in FIG. 1.

FIG. 6 is a cross-sectional view taken along line B1-B1 in FIG. 5.

FIG. 7 is a diagram illustrating a first layer pattern.

FIG. 8 is a diagram illustrating a second layer pattern.

FIG. 9 is a diagram illustrating a first printing plate for forming the first layer pattern.

FIG. 10 is a diagram illustrating a second printing plate for forming the second layer pattern.

FIG. 11 is a flowchart illustrating a solar-cell manufacturing process in the first embodiment.

FIG. 12 is a top view schematically illustrating a light receiving surface of a solar cell according to a second embodiment.

FIG. 13 is an enlarged view of main parts of the solar cell according to the second embodiment.

FIG. 14 is a cross-sectional view taken along line B2-B2 in FIG. 13.

FIG. 15 is an explanatory diagram of an output measuring apparatus for a solar cell according to a third embodiment and is a diagram illustrating the positional relation between light-receiving-surface bus electrodes of the solar cell, back-surface bus electrodes of the solar cell, and probe pins used for output measurement.

FIG. 16 is an explanatory diagram of the probe pin.

FIG. 17 is an enlarged view of main parts of the tip of the probe pin.

FIGS. 18(a) and 18(b) are explanatory diagrams of a lead attachment process.

### DESCRIPTION OF EMBODIMENTS

A manufacturing method for a solar cell and a solar cell according to embodiments of the present invention will be described below in detail with reference to the drawings. This invention is not limited to the embodiments and can be modified as appropriate without departing from the scope of the invention. In the drawings illustrated below, for easier understanding, the scales of respective layers or respective members may be shown differently from the actual scales. This also holds true for the relationships between the drawings. Hatching is not applied even to a cross-sectional view in some cases in order to facilitate visualization of the drawings.

### First Embodiment

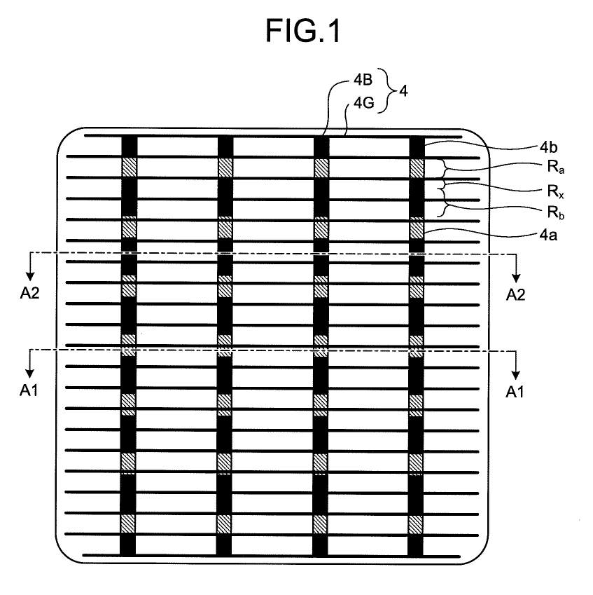

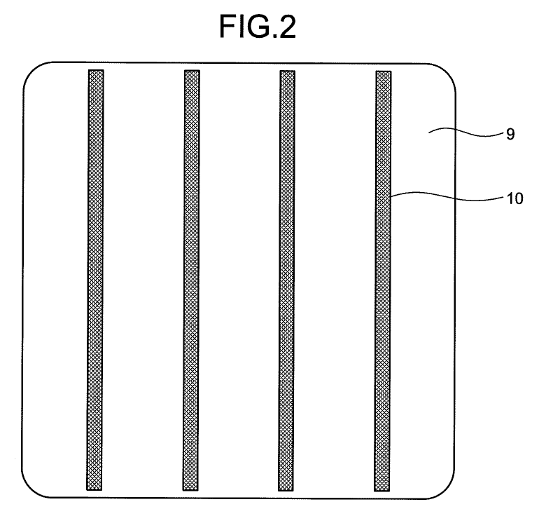

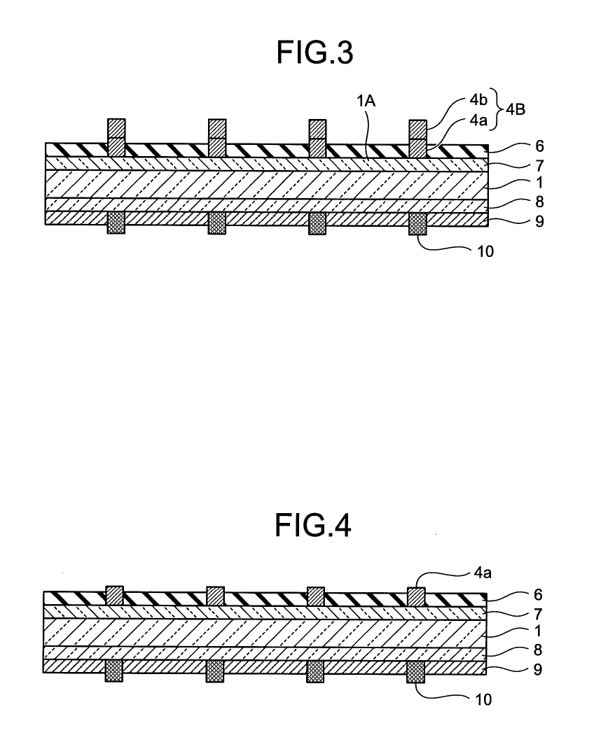

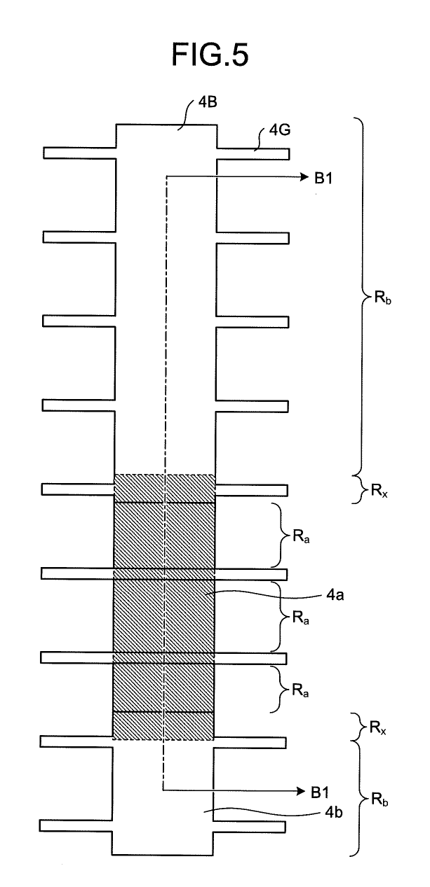

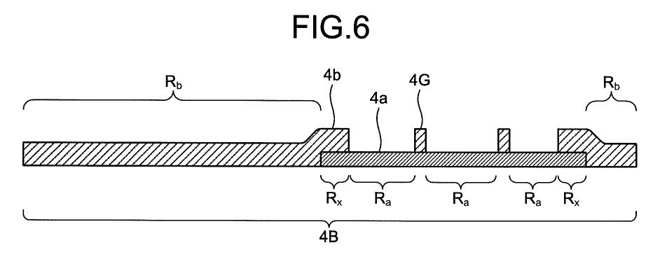

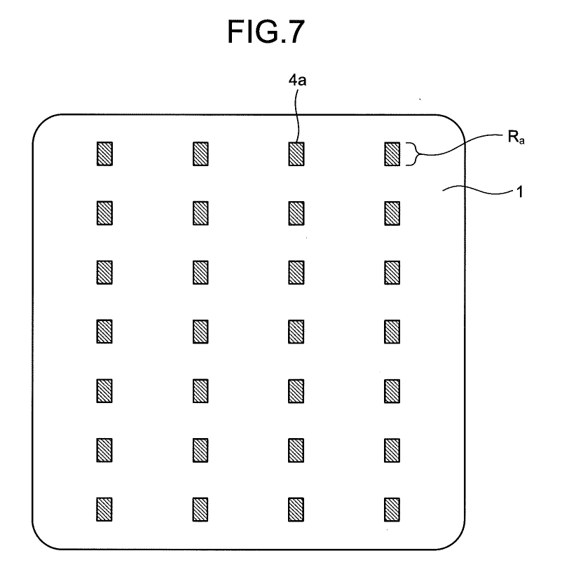

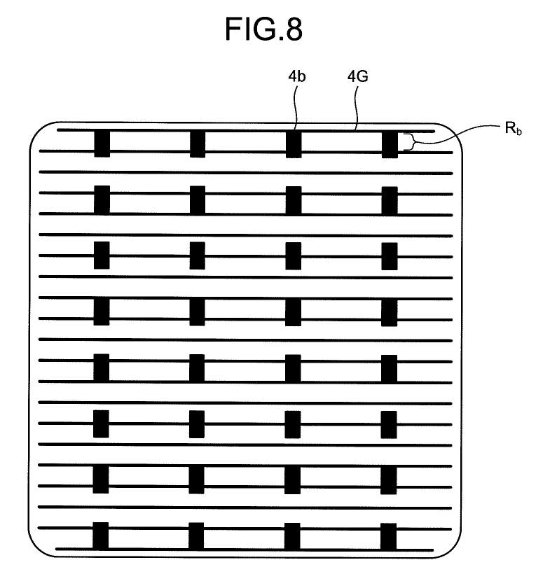

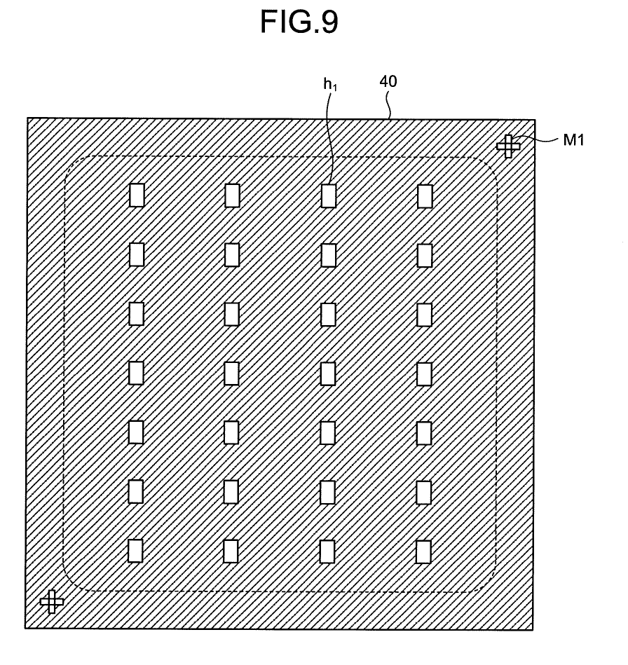

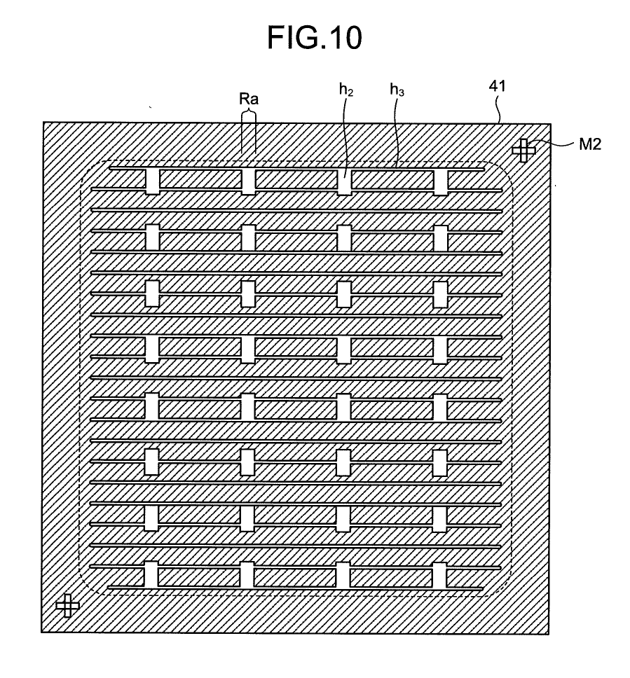

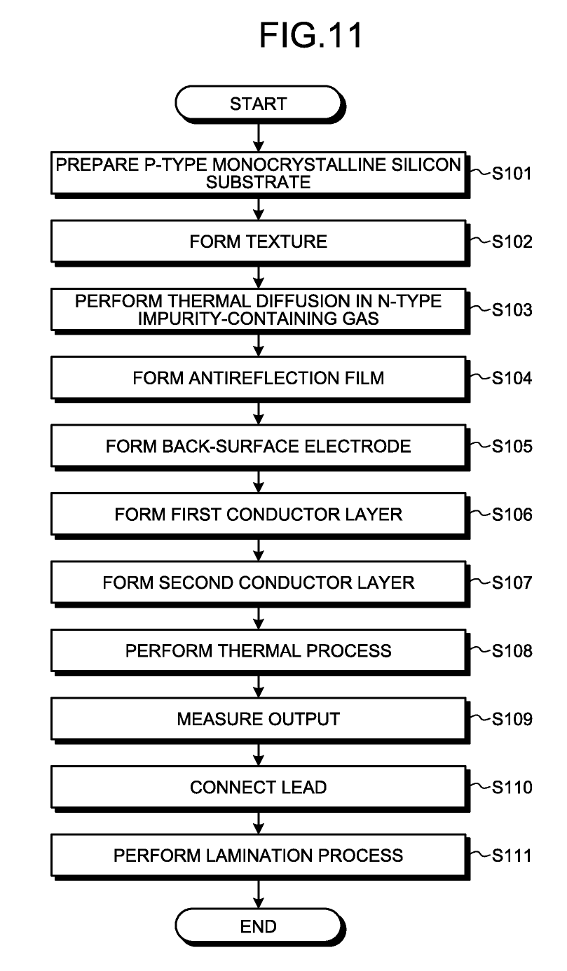

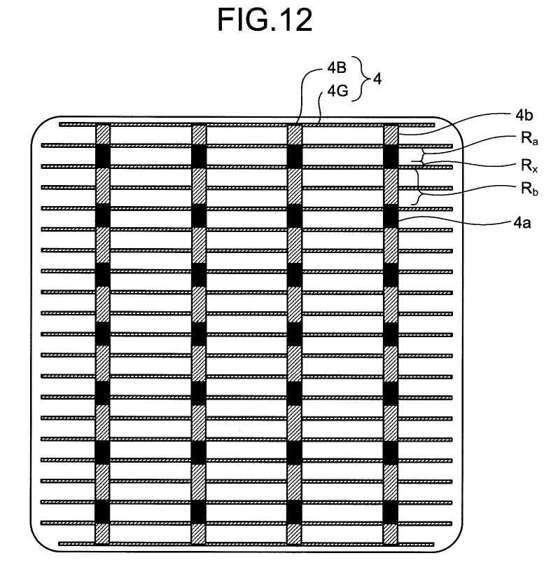

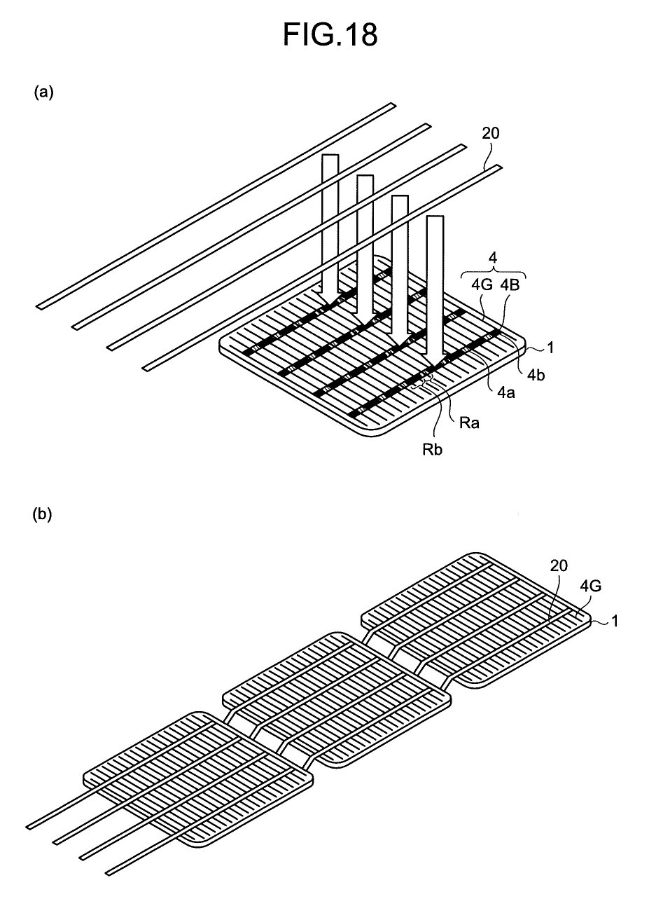

A manufacturing method for a solar cell and a solar cell according to a first embodiment of the present invention will be described below in detail with reference to the drawings. FIG. 1 is a top view schematically illustrating a light receiving surface of a solar cell according to the first embodiment; FIG. 2 is a bottom view schematically illustrating a back surface of the solar cell according to the first embodiment; FIG. 3 is a cross-sectional view taken along line A1-A1 in FIG. 1; and FIG. 4 is a cross-sectional view taken along line A2-A2 in FIG. 1. FIG. 5 is an enlarged view of the main parts in FIG. 1; and FIG. 6 is a cross-sectional view taken along line B1-B1 in FIG. 5. FIG. 7 is a diagram illustrating a first layer pattern; and FIG. 8 is a diagram illustrating a second layer pattern. FIG. 9 is a diagram illustrating a first printing plate for forming the first layer pattern; and FIG. 10 is a diagram illustrating a second printing plate for forming the second layer pattern. FIG. 11 is a flowchart illustrating a solar-cell manufacturing process in the first embodiment. As illustrated in FIGS. 1 to 4, the solar cell in the first embodiment includes, on the light receiving surface side of the solar cell substrate, a collection electrode 4, which includes grid electrodes 4G formed over an entire light receiving surface 1A in a distributed manner and light-receiving-surface bus electrodes 4B, which abut the grid electrodes 4G and are used for drawing current. In FIG. 1, FIG. 8, FIG. 10, FIG. 12, and FIG. 18, the illustration of the grid electrodes 4G is partially omitted for better understanding of the drawings.

The manufacturing method for a solar cell in the first embodiment includes, in order to form the collection electrode 4, a process of printing, in part of the region in which the light-receiving-surface bus electrodes 4B are to be formed, a first conductive paste by using a first printing plate 40, which is illustrated in FIG. 9 and has first openings h₁ including discontinuous portions extending in the longitudinal direction of the light-receiving-surface bus electrodes 4B, and forming a first conductor layer 4a illustrated in FIG. 7; and a process of printing a second conductive paste by using a second printing plate 41, which is illustrated in FIG. 10 and has second openings h₂, which partially overlap with the first openings h₁, and third openings h₃ corresponding to the grid electrodes 4G, and forming a second conductor layer 4b illustrated in FIG. 8. In the solar cell in the first embodiment, as illustrated in the enlarged views of the main parts in FIGS. 5 and 6, the light-receiving-surface bus electrode 4B has, in a portion in the longitudinal direction, overlapping regions R_{X}, in each of which the second conductor layer 4b is superimposed on the first conductor layer 4a and which are divided only in the longitudinal direction. In the first embodiment, intra-second-conductor-layer regions R_{b} excluding the overlapping regions R_{X} are probe installation regions, i.e., probe pressing regions. The grid electrodes 4G are formed from the second conductor layer 4b. It is desirable that the electrode patterns are designed such that the probe installation regions match the pressing regions used when tabbing wires are connected.

The solar-cell manufacturing process in the first embodiment will be described next. First, a silicon substrate is prepared. This silicon substrate is made of monocrystalline or polycrystalline and contains p-type semiconductor impurities, such as boron, or n-type semiconductor impurities, such as phosphorus. The silicon substrate used typically has a specific resistance of 0.1 Ω·cm or more to 6.0 Ω·cm or less. Hereinafter, as an example, a description will be given of a manufacturing method for a solar cell using a p-type monocrystalline silicon substrate 1. In a p-type monocrystalline silicon substrate preparation step S101, the p-type monocrystalline silicon substrate 1 is prepared as a substrate used for manufacturing a solar cell. The p-type monocrystalline silicon substrate 1 used typically has a plate-like shape having an area of 100 mm² to 160 mm² and a thickness of 0.1 mm or more to 0.3 mm or less.

In a texture formation step S102, a relief structure referred to as a texture is formed by etching the p-type monocrystalline silicon substrate 1 to a depth of about 2 μm or more to 20 μm or less, for example, with a high concentration of alkali, such as sodium hydroxide or potassium hydroxide, or a mixed solution of hydrofluoric acid and nitric acid so as to remove a contaminated layer or a mechanical damage caused when the p-type monocrystalline silicon substrate 1 is cut to a constant thickness and then by drying the p-type monocrystalline silicon substrate 1. A texture causes multiple reflection of light on the light receiving surface of the solar cell; therefore, light is confined in the solar cell and is guided efficiently into the semiconductor, and light is not easily returned to the light receiving surface.

Consequently, the reflectivity is reduced. This contributes to the improvement of the conversion efficiency.

Thereafter, in a thermal diffusion step S103, the p-type monocrystalline silicon substrate 1 is placed in a high-temperature gas with a temperature from 800° C. to 1000° C. that contains an n-type impurity-containing gas, such as POCl₃, and then thermal diffusion is performed. In the thermal diffusion step S103, an n-type diffusion layer 7 with a sheet resistance of about 30 Ω/□ or more to 150 Ω/␣ or less is formed in the light receiving surface 1A by using a thermal diffusion method of diffusing an n-type impurity element, such as phosphorus, into the entire surface of the p-type monocrystalline silicon substrate 1. Although the n-type diffusion layer 7 is also formed in some cases on both the front and back surfaces and on the end surfaces of the p-type monocrystalline silicon substrate 1, the unnecessary n-type diffusion layers 7 on the back surface and the end surfaces are removed by immersing them into a hydrofluoric-nitric acid solution. Thereafter, phosphorus glass formed by the thermal diffusion is removed by immersing it into an aqueous hydrofluoric acid solution of not less than 1% and not more than 15% for a few minutes and then the p-type monocrystalline silicon substrate 1 is cleaned with pure water.

Furthermore, in an antireflection film formation step S104, an antireflection film 6 is formed on the side where the light receiving surface 1A of the p-type monocrystalline silicon substrate 1 is located. The antireflection film 6 functions as an antireflection film and also as a passivation film. The antireflection film 6 is formed from Si₃N₄ by using, for example, a plasma CVD method of turning a mixed gas of, for example, SiH₄, NH₄, and N₂, into plasma by using glow discharge decomposition and then depositing them. The antireflection film 6 has a thickness of about 60 nm to 100 nm and has a refractive index of about 1.9 to 2.3. The antireflection film 6 is provided in order to prevent light from being reflected from the surface of the p-type monocrystalline silicon substrate 1 and to effectively capture light. Si₃N₄ has a passivation effect on the n-type diffusion layer 7 and the antireflection film 6 thus functions also as a passivation film. The antireflection film 6 has both a passivation function and an antireflection function and thus can improve the electrical properties of the solar cell.

Next, in a back-surface-electrode formation step S105, back-surface bus electrodes 10 are first formed on the back surface of the p-type monocrystalline silicon substrate 1, for example, by a screen printer using a printing plate. The back-surface bus electrodes 10 are screen printed as illustrated in FIG. 2 by using, for example, a conductive paste that contains silver powder in an amount of about 30 wt % or more to 80 wt % or less, glass frit, and resin and is mixed with an organic solvent, and the back-surface bus electrodes 10 are then dried at a temperature from about 150° C. or higher to 220° C. or lower. Then, back-surface aluminum electrodes 9 are screen printed in a region other than the region where the back-surface bus electrodes are formed by using, for example, a conductive paste that contains aluminum, glass frit, resin, and the like and is mixed with an organic solvent. The p-type monocrystalline silicon substrate 1 on which the back-surface aluminum electrodes 9 and the back-surface bus electrodes 10 are formed is then dried again at a temperature from about 150° C. or higher to 220° C. or lower. In a firing process, which will be described later, aluminum diffuses into the p-type monocrystalline silicon substrate 1 from the back-surface aluminum electrodes 9 and a BSF layer 8 formed from a p-type diffusion layer is thus formed.

Next, the light-receiving-surface bus electrodes 4B and the grid electrodes 4G are, for example, formed sequentially by a screen printer using the first and second printing plates 40 and 41. As illustrated in FIG. 9, the first printing plate 40 has the first openings h₁ including discontinuous portions extending in the longitudinal direction. As illustrated in FIG. 10, the second printing plate 41 has the second openings h₂ partially overlapping with the first openings h₁ and has the third openings h₃ corresponding to the grid electrodes 4G. Alignment marks M1 and M2 are respectively provided on the first and second printing plates 40 and 41 and printing is performed in such a manner that the pattern formed by the alignment mark M1 of the first printing plate 40 matches the alignment mark M2 of the second printing plate 41. The light-receiving-surface bus electrodes 4B can be formed by the combination of the first openings h₁ and the second openings h₂. First, in a first-conductor-layer formation step S106, the first printing plate 40 is used to print a first conductive paste as part of each of the light-receiving-surface bus electrodes 4B and thereby the first conductor layer 4a is formed. FIG. 7 is a schematic diagram illustrating the substrate on which the first conductor layer is formed.

Next, in a second-conductor-layer formation step S107, the second printing plate 41 is used to print a second conductive paste and thereby the second conductor layer 4b is formed. In FIG. 8, which is a schematic diagram illustrating the substrate on which the second conductor layer is formed, the illustration of the first conductor layer 4a is omitted and only the pattern of the second conductor layer 4b is illustrated for better understanding of the drawings. The light-receiving-surface bus electrode 4B has, in a portion in the longitudinal direction, the overlapping regions R_{X}, in each of which the second conductor layer 4b is superimposed on the first conductor layer 4a. The conductive paste used here, for example, contains silver powder in an amount of about 70 wt % or more to 95 wt % or less, glass frit, and resin and is mixed with an organic solvent. The conductive paste is printed into an electrode pattern of the grid electrodes 4G and part of each of the light-receiving-surface bus electrodes 4B on the antireflection film 6 and is then dried at a temperature from about 150° C. or higher to 220° C. or lower.

The first and second printing plates 40 and 41 used here each have a structure in which a mesh made of stainless steel, nickel, or polyether is coated with emulsion. The first and second printing plates 40 and 41 are, for example, screen printing plates having openings formed by removing emulsion layers in an electrode shape pattern. The grid electrodes 4G have a line width of 20 μm or more to 150 μm or less, a thickness of 5 μm or more to 20 μm or less, and a pitch of 1.0 mm or more to 2.5 mm or less. The light-receiving-surface bus electrodes 4B have a line width of 0.7 mm or more to 2.0 mm or less and a thickness of about 5 μm or more to 20 μm or less. Normally, all the light-receiving-surface bus electrodes 4B and the grid electrodes 4G are usually printed collectively by using a printing plate having openings in a pattern corresponding to the light-receiving-surface bus electrodes 4B and the grid electrodes 4G.

After the collection electrode 4 is printed on the light receiving surface side as described above, a thermal processing step S108 is performed, in which the p-type monocrystalline silicon substrate 1 on which the collection electrode 4 is printed is fired in a firing furnace for 3 seconds or more to 60 seconds or less at a temperature from 600° C. or higher to 850° C. or lower so as to form the light-receiving-surface bus electrodes 4B, the grid electrodes 4G, the back-surface bus electrodes 10, and the back-surface aluminum electrodes 9 at the same time. Consequently, the solar cell is obtained. The finished solar cell is irradiated with artificial sunlight while probe pins are brought into contact with the light-receiving-surface bus electrodes 4B and the back-surface bus electrodes 10 at some locations, and the output of the solar cell is measured in an output measurement step S109.

When output measurement is performed, the probe pins are brought into contact with the light-receiving-surface bus electrodes 4B only in the intra-second-conductor-layer regions R_{b}, in which there is no pattern of the first conductor layer 4a, i.e., in the region in which only the second conductor layer 4b is present. By forming the region with which the probe pins come into contact into a shape that is always flat, partial contact of the probe pins does not occur, thus ensuring stable and reliable measurement. Moreover, while the probe pins are sliding, the probe pins come into contact with the flat portions of the light-receiving-surface bus electrodes 4B; therefore, the probe pins are unlikely to receive a force other than the force that is applied to the probe pins vertically and this prevents the sliding portions from being degraded.

Thereafter, in a lead connection step S110, leads referred to as tabbing wires are soldered to the light-receiving-surface bus electrodes 4B. FIGS. 18(a) and 18(b) illustrate explanatory diagrams of the lead attachment process. As illustrated in FIG. 18(a), leads 20 are positioned on the light-receiving-surface bus electrodes 4B and are soldered to the light-receiving-surface bus electrodes 4B. As illustrated in FIG. 18(a), which illustrates the pressing portions as indicated by the arrows, on the light-receiving-surface bus electrodes 4B, soldering tools (not illustrated) are pressed against the intra-second-conductor-layer regions R_{b}, in which there is no pattern of the first conductor layer 4a, i.e., the region in which only the second conductor layer 4b is present, so as to connect the leads 20 to the light-receiving-surface bus electrodes 4B. FIG. 18(b) illustrates solar cells connected in series by the leads 20.

In this manner, inter-cell connection is achieved by soldering the leads 20 referred to as tabbing wires to the light-receiving-surface bus electrodes 4B. At this point in time, as illustrated in FIG. 6, the regions that are mechanically pressed during soldering are on the light-receiving-surface bus electrodes 4B in the intra-second-conductor-layer regions R_{b}, in which there is no pattern of the first conductor layer 4a, i.e., in the region in which only the second conductor layer 4b is present. Accordingly, the probe pins always press against a region that is flat and low; therefore, partial contact of the probe pins does not occur, thus ensuring that the entire surfaces of the light-receiving-surface bus electrodes 4B are pressed against. Consequently, reliable connection is achieved. Specifically, the intra-second-conductor-layer regions R_{b}, in which there is no pattern of the first conductor layer 4a, i.e., the second conductor layer 4b excluding the regions overlapping with the first conductor layer 4a, correspond to the light-receiving-surface bus electrodes 4B with which the probe pins come into contact during output measurement and against which the leads are pressed during lead connection. A solar cell string is formed by connecting solar cells in series by the leads and a solar cell array is formed by connecting solar cell strings by connection members.

Finally, in a lamination processing step S111, a translucent glass substrate is placed on the light receiving surface side and a resin back sheet is placed on the back surface side, the translucent glass substrate and the resin back sheet sandwich the solar cell array to which leads are connected with a sealing resin therebetween, which is then heated so as to seal the solar cell array. Consequently, a solar cell module is obtained. Then, a frame is formed so as to obtain a solar cell panel.

The solar cell in the first embodiment includes the grid electrodes and the bus electrodes provided at least on one of the light receiving surface and the back surface, the grid electrodes and the bus electrodes are formed by performing screen printing two or more times, and the first printed portion and the second printed portion overlap with each other. The overlapping portions are present only on the bus electrodes and are located at the positions other than the positions in which the probe pins are brought into contact with the bus electrodes during output measurement and other than the positions in which the leads are mechanically held down during lead soldering.

The overlapping regions R_{X}, in each of which the divided light-receiving-surface bus electrodes 4B overlap with each other, are arranged only in the longitudinal direction of the light-receiving-surface bus electrodes 4B; therefore, a highly accurate pattern can be formed regardless of the alignment accuracy of the printer to be used. Moreover, the overlapping region R_{X}, in which the light-receiving-surface bus electrode 4B and the grid electrode 4G overlap with each other, may be printed continuously such that the grid electrode 4G passes across the light-receiving-surface bus electrode 4B, or they may be printed such that the grid electrode 4G is interrupted in such a manner that part of the interrupted grid electrode 4G is superimposed on the light-receiving-surface bus electrode 4B or the light-receiving-surface bus electrode 4B is superimposed on part of the interrupted grid electrode 4G.

In the present embodiment, the first conductor layer is first printed and the second conductor layer is then printed; however, either of the divided printing patterns, i.e., the first conductor layer and the second conductor layer, may be printed first.

According to the first embodiment, because the design ensures that electrodes have a flat region in which only the pattern of the second conductor layer 4b is included to bring the probe pins into contact therewith, degradation of the probe pins is not accelerated, where the probe pins are used for measuring the output of the solar cell in which light-receiving-surface bus electrodes and grid electrodes are formed in a divided manner. Moreover, it is possible to form light-receiving-surface bus electrodes that have a high adhesive strength to the leads, i.e., tabbing wires.

Furthermore, the solar cell is configured such that the regions in each of which a plurality of divided electrode patterns overlap with each other are provided only in the bus electrode portions to which leads are to be connected and the electrode patterns do not overlap with each other on the grid electrodes. When this configuration is applied to the light receiving surface side, a reduction in the light receiving area can be inhibited.

According to the first embodiment, in a case where the light-receiving-surface bus electrodes and the grid electrodes of a solar cell, which are made of electrode materials different from each other, are formed by performing printing a plurality of times, an effect is obtained where it is possible to obtain a solar cell that has excellent contact with measurement probes and has excellent connectivity with tabbing wires.

With the conventional manufacturing methods, the whole electrode pattern of the light-receiving-surface electrodes is formed from a paste having a high silver powder content, which leads to an increase in manufacturing cost.

Light-receiving-surface bus electrodes typically have a larger line thickness than grid electrodes. Moreover, in solar cell modules available in the market, leads that are used for extracting collected carries to an external destination are connected to light-receiving-surface bus electrodes. Thus, even when the light-receiving-surface bus electrodes have a resistivity higher than the grid electrodes, the conversion efficiency of the solar cell module is not significantly affected. Thus, the conventional solar cells are manufactured by the following method so as to reduce the manufacturing cost. That is, the light-receiving-surface bus electrodes and the grid electrodes are divided into two or more portions, the light-receiving-surface bus electrodes printed at the first time are formed by screen printing a conductive paste containing a relatively small amount of silver powder, for example, containing at least 30 wt % and up to 70 wt % silver powder or by screen printing a conductive paste containing, instead of silver powder, metal powder, such as copper powder, that is cheaper than silver powder and then drying the conductive paste at a temperature from about 150° C. or higher to 220° C. or lower, and thereafter only grid electrodes are formed at the second printing by screen printing a conductive paste containing a relatively large amount of silver powder, for example, containing at least 70 wt % and up to 95 wt % silver powder, thereby manufacturing a solar cell.

However, with the conventional methods in which the light-receiving-surface bus electrodes are formed after the grid electrodes are formed in such a manner that the light-receiving-surface bus electrodes are superimposed on the grid electrodes or the grid electrodes are formed so as to be superimposed on the light-receiving-surface bus electrodes, adverse effects arise in the subsequent processes due to the irregularities on the light-receiving-surface bus electrodes, and moreover, there are disadvantages such as a reduction in the light receiving area due to the overlapping portions that protrude over the light receiving surface.

According to the first embodiment, the problems of the conventional solar cells described above can be solved; therefore, it is possible to obtain a solar cell that has excellent contact with measurement probes and has excellent connectivity with tabbing wires.

In the first embodiment, the first conductor layer 4a forms, as a first layer, part of each of the light-receiving-surface bus electrodes 4B including discontinuous portions and then the second conductor layer 4b forms the grid electrodes 4G and part of each of the light-receiving-surface bus electrodes 4B. Because the grid electrodes 4G are formed on the upper layer side, the light-receiving-surface bus electrodes 4B can be formed without passing across the grid electrodes 4G. Thus, the width of the bus electrodes can be prevented from increasing due to bleeding at the intersections. Therefore, a reduction in photoelectric conversion area can be inhibited.

Although the manufacturing method for a solar cell in the first embodiment can be applied to the formation of electrodes on the light receiving surface, this method can also be applied to the back surface of a solar cell in which bus electrodes and grid electrodes are formed on the back surface, such as a bifacial solar cell or a back-contact solar cell.

As described above, in the solar cell in the first embodiment, one of the divided electrode patterns corresponds to the positions in which the probe pins are brought into contact with the bus electrodes when the output of the solar cell is measured in the output measuring process and the portions in which the leads are mechanically held down during lead connection that involves pressurization, such as a solder connection, in the lead connecting process. The one of the divided electrode patterns has a shape that takes into account the pattern printing alignment accuracy in the process of printing, in the longitudinal direction of the light-receiving-surface bus electrodes, the portions that take full account of the alignment accuracy for the solar cell during both processes described above and the portions to be overlapped with the other of the divided electrode patterns, i.e., the overlapping regions. The electrode patterns are designed such that a printed pattern in which the grid electrodes are added to the shape of the light-receiving-surface bus electrodes is obtained. The other of the divided electrode patterns has a shape obtained by combining the portions that connect the interrupted light-receiving-surface bus electrodes in the longitudinal direction and the portions that overlap with the light-receiving-surface bus electrodes in the one of the divided electrode patterns. The overlapping portions are formed only in the longitudinal direction of the light-receiving-surface bus electrodes in consideration of the printing alignment accuracy in a similar manner to the one of the divided electrode patterns. A printing plate used for screen printing and having openings in a divided electrode shape pattern is manufactured for each of the divided electrode shape patterns. Then, screen printing is performed a plurality of times so as to form the light-receiving-surface electrodes illustrated in FIG. 1.

In the first embodiment, the intra-second-conductor-layer regions R_{b} excluding the overlapping regions R_{X} are the probe installation regions and the pressing regions used when tabbing wires are connected; however, when intra-first-conductor-layer regions Rₐ, which are on the light-receiving-surface bus electrodes excluding the overlapping regions R_{X}, are sufficiently broad, the intra-first-conductor-layer regions Rₐ may be the probe installation regions and the pressing regions used when tabbing wires are connected.

The electrodes formed in the electrode pattern of the second conductor layer contain more silver powder than the conductive paste used for printing the electrode pattern formed from the first conductor layer; therefore, the electrode pattern formed from the second conductor layer is generally thicker than the electrode pattern formed from the first conductor layer. Thus, when screen printing is performed a plurality of times in order to form electrodes, the electrode pattern formed from the first conductor layer having a relatively low silver powder content is formed first. The electrode pattern formed from the first conductor layer is printed first and then the electrode pattern formed from the second conductor layer is printed one or more times so as to be overlapped with the electrode pattern formed from the first conductor layer. With this order, it is easy to obtain the electrode shape close to the tailored electrode shape; therefore, the electrode patterns are often formed in this order. However, the electrode pattern formed from the second conductor layer may be printed first.

In other words, in the first embodiment, the divided shape patterns of the bus electrodes and the grid electrodes include a second divided shape pattern that includes the grid electrodes and the portions in which the leads and the bus electrodes are mechanically held down in the process of connecting the leads to the bus electrodes;

and a first divided shape pattern that includes the remaining bus electrodes.

When the portions in which the leads and the bus electrodes are mechanically held down in the process of connecting the leads to the bus electrodes match the portions with which the probe pins come into contact during output measurement of the solar cell, both of them can be formed from the second divided shape pattern that is obtained by using the second printing plate and that includes the grid electrodes and the portions in which the leads are mechanically held down and the first divided shape pattern that is obtained by using the first printing plate and that includes the remaining bus electrodes. If the portions in which the leads and the bus electrodes are mechanically held down in the process of connecting the leads to the bus electrodes do not match the portions with which the probe pins come into contact during output measurement of the solar cell, it is sufficient if the divided shape pattern that is obtained by using the second printing plate and that includes the bus electrodes and the grid electrodes is adjusted such that the divided shape pattern includes both of the portions with which the probe pins come into contact during output measurement of the solar cell and the portions in which the leads are mechanically held down.

### Second Embodiment

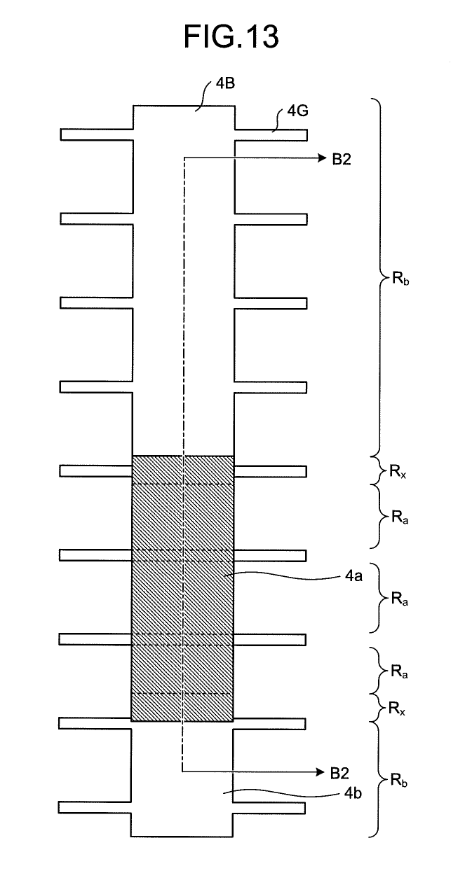

A solar cell and a manufacturing method for a solar cell according to a second embodiment of the present invention will be described below in detail with reference to the drawings. FIG. 12 is a top view schematically illustrating a light receiving surface of a solar cell according to the second embodiment; FIG. 13 is an enlarged view of the main parts of the solar cell according to the second embodiment; and FIG. 14 is a cross-sectional view taken along line B2-B2 in FIG. 13. In the solar cell in the first embodiment, the grid electrodes 4G are formed from the second conductor layer 4b and the light-receiving-surface bus electrodes 4B are formed from the first conductor layer 4a and the second conductor layer 4b. In the second embodiment, the first conductor layer 4a and the second conductor layer 4b are formed in reverse order to the order in the first embodiment. In the solar cell in the second embodiment, the grid electrodes 4G are formed from the second conductor layer 4b and the light-receiving-surface bus electrodes 4B are formed from the first conductor layer 4a and the second conductor layer 4b. In the second embodiment, the light-receiving-surface bus electrode 4B has, in a portion in the longitudinal direction, the overlapping regions R_{X}, in each of which the first conductor layer 4a overlaps with the second conductor layer 4b, in a similar manner to the first embodiment; however, the second embodiment is different from the first embodiment in that the first conductor layer 4a is superimposed on the second conductor layer 4b. In order to form the collection electrode 4, the second conductive paste is first printed by using the second printing plate 41, which is illustrated in FIG. 10 and has the second openings h₂ and the third openings h₃ corresponding to the grid electrodes 4G so as to form the second conductor layer 4b. Next, the first conductor layer 4a is printed by using the first printing plate 40, which is illustrated in FIG. 9 and has the first openings h₁ partially overlapping with the second openings h₂. The manufacturing method for a solar cell includes, subsequent to the process of printing the second conductive paste by using the second printing plate 41, which has the second openings h₂ partially overlapping with the first openings h₁ and the third opening h₃ corresponding to the grid electrodes 4G, and forming the second conductor layer 4b, a process of printing the first conductive paste on part of each of the bus electrodes by using the first printing plate 40, which has the first openings h₁ including discontinuous portions extending in the longitudinal direction of the light-receiving-surface bus electrodes 4B, and forming the first conductor layer 4a. In the solar cell in the second embodiment, the light-receiving-surface bus electrode 4B has, in a portion in the longitudinal direction, the overlapping regions R_{X}, in each of which the first conductor layer 4a is superimposed on the second conductor layer 4b. In the second embodiment, the intra-second-conductor-layer regions R_{b} excluding the overlapping regions R_{X} are the probe installation regions and the pressing regions used when tabbing wires are connected. The intra-second-conductor-layer regions R_{b} are regions on which the first conductor layer 4a is not present.

With the configuration in the second embodiment, the first layer of the divided electrode patterns corresponds to the positions in which the probe pins are brought into contact with the bus electrodes when the output of the solar cell is measured in the output measuring process and the portions in which the leads are mechanically held down during lead connection that involves pressurization, such as a solder connection, in the lead connecting process. Consequently, highly reliable mounting can be achieved. In other words, it is possible to obtain a solar cell that has excellent contact with measurement probes and has excellent connectivity with tabbing wires.

In the second embodiment, the second conductor layer 4b forms the grid electrodes 4G and part of each of the light-receiving-surface bus electrodes 4B as a first layer and then the first conductor layer 4a forms the bus electrodes including discontinuous portions. Because the grid electrodes 4G are formed on the lower layer side, the grid electrodes 4G are formed on a smooth substrate surface of the solar cell and thus the grid electrodes 4G with a highly accurate fine pattern can be formed.

In other words, in the second embodiment, the divided shape patterns of the bus electrodes and the grid electrodes include a third divided shape pattern that includes the grid electrodes and the bus electrodes that include the portions in which the leads and the bus electrodes are mechanically held down in the process of connecting the leads to the bus electrodes; and a fourth divided shape pattern that includes part of each of the bus electrodes.

When the portions in which the leads and the bus electrodes are mechanically held down in the process of connecting the leads to the bus electrodes match the portions with which the probe pins come into contact during output measurement of the solar cell, both of them can be formed from the third divided shape pattern that includes the grid electrodes and the portions in which the leads are mechanically held down and the fourth divided shape pattern that includes the remaining bus electrodes. If the portions in which the leads and the bus electrodes are mechanically held down in the process of connecting the leads to the bus electrodes do not match the portions with which the probe pins come into contact during output measurement of the solar cell, it is sufficient if the divided shape pattern that includes the bus electrodes and the grid electrodes is adjusted such that the divided shape pattern includes both of the portions with which the probe pins come into contact during output measurement of the solar cell and the portions in which the leads are mechanically held down.

In the present embodiment, the first conductor layer and the second conductor layer are not necessarily formed from different conductive pastes and may be formed from the same conductive paste. It is obvious that each of the layers can be formed by performing a plurality of printing processes.

### Third Embodiment

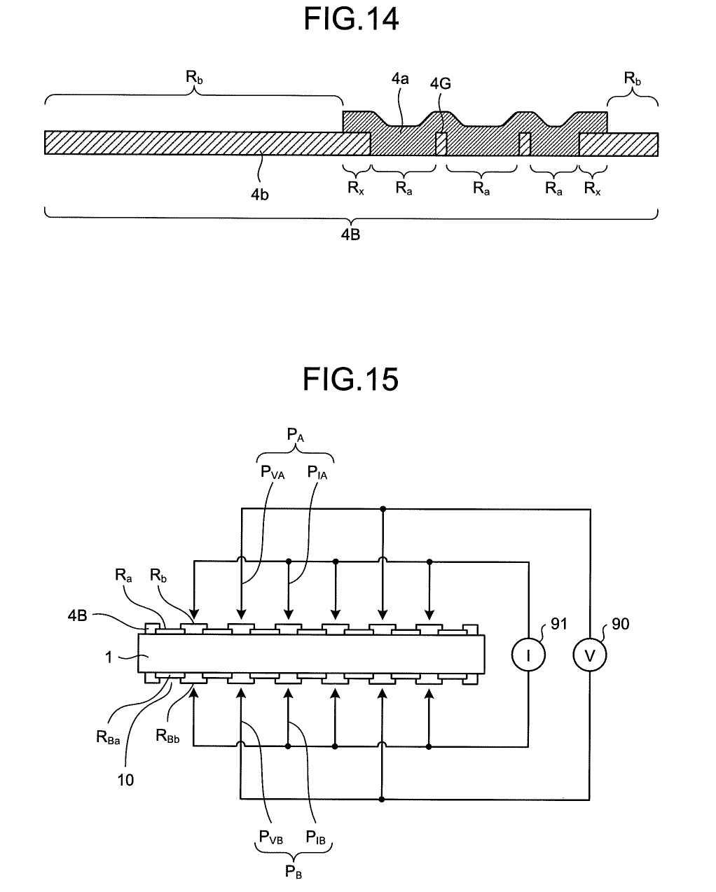

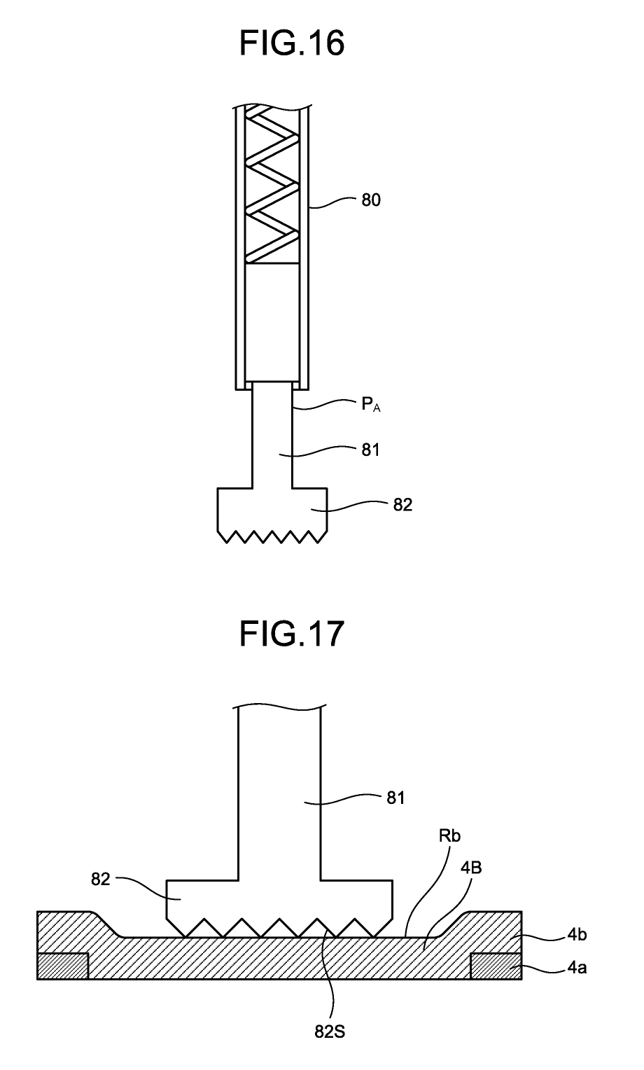

An output measuring apparatus for a solar cell will be described here. FIG. 15 is an explanatory diagram of an output measuring apparatus for a solar cell according to a third embodiment and is a diagram illustrating the positional relation between the light-receiving-surface bus electrodes 4B of the solar cell, the back-surface bus electrodes 10 of the solar cell, and probe pins P_{A} and P_{B} used for output measurement; FIG. 16 is an explanatory diagram of the probe pin P_{A}; and FIG. 17 is an enlarged view of the main parts of the tip of the probe pin P_{A}. When the output of the solar cell produced in the first embodiment is measured, as illustrated in FIG. 15, the probe pins P_{A} and P_{B} used for output measurement are pressed against the light-receiving-surface bus electrodes 4B and the back-surface bus electrodes 10, respectively, and the output between the probe pins P_{A} and P_{B} is measured. In the present embodiment, for ease of understanding, the number of regions that are formed from one second conductor layer, i.e., the intra-second-conductor-layer regions R_{b}, which are measuring portions for the light-receiving-surface bus electrode 4B and the back-surface bus electrode 10 and arrayed separately in the longitudinal direction, is eight. In other words, the light-receiving-surface bus electrode 4B includes eight pad electrodes arranged sequentially from the cell end. The output of the solar cell is measured by bringing each of the probe pins P_{A} and the probe pins P_{B} into contact with the pad electrodes at six locations, i.e., the second to seventh pad electrodes excluding the first pad electrode and the eighth pad electrode at both ends. Current terminals P_{IA} and P_{IB} of the probe pins are pressed against the second, fourth, fifth, and seventh pad electrodes among the pad electrodes. Voltage terminals P_{VA} and P_{VB} of the probe pins are pressed against the third and sixth pad electrodes. The voltage terminals P_{VA} and P_{VB} of the probe pins are connected to a voltmeter 90 and the current terminals P_{IA} and P_{IB} of the probe pins are connected to an ammeter 91.

In a state where the current terminals P_{IA} and P_{IB} and the voltage terminals P_{VA} and P_{VB} are pressed against the pad electrodes as described above, the voltages at the voltage terminals P_{VA} and P_{VB} are measured while changing the values of the currents flowing in the current terminals P_{IA} and P_{IB}, whereby the current-voltage characteristics (IV characteristics) of the solar cell are measured.

As illustrated in the cross section of the probe pin in FIG. 16 and in the enlarged view of the main parts of the tip of the probe pin and the pressing region of the light-receiving-surface bus electrode 4B in FIG. 17, the probe pins P_{A} and P_{B} each include a holder socket 80; a pin 81 elastically housed in the holder socket 80 such that the pin 81 is vertically movable in the holder socket 80; and a disk-shaped contact portion 82 provided at the tip of the pin 81. The lower-side surface of the contact portion 82 comes into contact with the electrodes of the solar cell. A contact surface 82S of the disk-shaped contact portion 82, which comes into contact with the pad electrodes, has irregularities. For example, the light-receiving-surface bus electrodes 4B after firing are not completely flat and have irregularities. Thus, by forming the disk-shaped contact portion 82 having irregularities at the tip of each of the probe pins P_{A} and P_{B} as such, it is possible to reduce the contact resistance between the probe pins P_{A} and P_{B} and the light-receiving-surface bus electrodes 4B and the back-surface bus electrodes 10. FIG. 16 is a cross-sectional view of the probe pin. During measurement, the pin 81 is brought into contact with and presses against the light-receiving-surface bus electrodes 4B and the back-surface bus electrodes 10 of the solar cell, and the pin 81 and the holder socket 80 are electrically connected via the sliding portion.

An alloy portion is formed in the overlapping region R_{X}, in which the first conductor layer 4a overlaps with the second conductor layer 4b, and irregularities larger than those on the first conductor layer 4a are formed on the overlapping region R_{X} after firing. Thus, when the probe pin comes into contact with the alloy portion or the overlapping region R_{X} during IV measurement for the solar cell, because large irregularities are formed in the overlapping region R_{X}, the tip of the probe pin partially comes into contact with the overlapping region R_{X} and thus the sliding portion wears quickly. In the present embodiment, the electrode patterns are designed and arranged such that the probe pin P_{A} comes into contact with the intra-second-conductor-layer regions R_{b} of the light-receiving-surface bus electrodes 4B formed from one second conductor layer. Moreover, in the third embodiment, with respect to the back-surface bus electrodes 10, the back-surface grid electrodes (partially not illustrated) and part of each of the back-surface bus electrodes are formed from the first back-surface conductor layer in a pattern similar to the pattern on the light receiving side and the back-surface bus electrodes formed from the second back-surface conductor layer are formed so as to have partially overlapping regions. The electrode patterns are designed and arranged such that the probe pin P_{B} comes into contact not with intra-first-back-surface-conductor-layer regions R_{Ba} formed from one first conductor layer forming the back-surface bus electrodes 10 but with intra-second-back-surface-conductor-layer regions R_{Bb} formed from one second conductor layer. Accordingly, wear of the probe pins P_{A} and P_{B} can be inhibited. Therefore, it is possible to inhibit an increase in the contact resistance between the probe pins P_{A} and P_{B} and the light-receiving-surface bus electrodes 4B and the back-surface bus electrodes 10 of the solar cell and thus the measurement accuracy can be stabilized.

In the third embodiment, a description has been given of the pressing portions against which the probe pins used for output measurement are pressed. The electrode patterns are designed and arranged such that the pressing portions against which the tip of a joining tool used for attaching the leads to the bus electrodes is pressed are located in the intra-second-conductor-layer regions R_{b} formed from one second conductor layer forming the light-receiving-surface bus electrodes 4B. In a similar manner to that illustrated in FIG. 17, because the pressing portions are located in the intra-second-conductor-layer regions R_{b} formed from one second conductor layer, the leads can be reliably joined to the light-receiving-surface bus electrodes or the back-surface bus electrodes.

When the p-type monocrystalline silicon substrate 1 has an area of 100 mm² to 160 mm², as illustrated in FIG. 15, voltage terminals P_{V} are provided at two locations in the longitudinal direction of the bus electrodes and two current terminals P_{I} are provided before and after each of the voltage terminals P_{V} in the longitudinal direction. Consequently, the current-voltage characteristics (IV characteristics) of the solar cell can be accurately measured. In other words, providing two voltage terminals and four current terminals, i.e., six terminals in total, enables highly accurate measurement of the current-voltage characteristics (IV measurement). It is sufficient, in order to bring these voltage terminals P_{V} and current terminals P_{I} into contact with the intra-second-conductor-layer regions R_{b} corresponding to the pressing portions with which the voltage terminals P_{V} and current terminals P_{I} come into contact, to provide the intra-second-conductor-layer regions R_{b} separately at six locations. In other words, by providing the intra-second-conductor-layer regions R_{b} separately at six locations, it is possible to obtain a solar cell that enables highly accurate measurement of the current-voltage characteristics (IV characteristics) to be taken.

Furthermore, by providing the intra-second-conductor-layer regions R_{b} corresponding to the pressing portions on the outside of the intra-second-conductor-layer regions R_{b} corresponding to the pressing portions with which the voltage terminals P_{V} and the current terminals P_{I} come into contact and by connecting the leads, the current generated in the solar cell can be effectively collected and thus the conversion efficiency can be improved. To that end, it is satisfactory if the intra-second-conductor-layer regions R_{b} corresponding to the pressing portions are provided separately at eight locations. In other words, by providing the intra-second-conductor-layer regions R_{b} separately at eight locations, it is possible to obtain a solar cell that enables highly accurate measurement of the current-voltage characteristics (IV characteristics) to be taken and that can provide improved conversion efficiency by efficiently collecting current.

As described above, the divided shape patterns of the bus electrodes and the grid electrodes include the first divided shape pattern that corresponds to the pressing portions and includes the bus electrodes and the grid electrodes; and the second divided shape pattern that includes the remaining bus electrodes. Therefore, it is possible to obtain a solar cell that enables highly accurate measurement of the current-voltage characteristics (IV characteristics) to be taken and that can provide improved conversion efficiency by efficiently collecting current. It is desirable that the number of first divided shape patterns is six to eight.

In the first to third embodiments, one of the layers forms the bus electrodes and the grid electrodes and the other layer forms the bus electrodes including discontinuous portions, which is not restrictive. The shape pattern of the grid electrodes is not necessarily formed from only one of the layers and may be formed from a plurality of layers. It is sufficient if a screen printing process is performed a plurality of times such that the bus electrode is divided in the longitudinal direction and the divided bus electrodes have overlapping regions only in the longitudinal direction. With this configuration, in a case where the bus electrodes and the grid electrodes of a solar cell are formed by performing printing a plurality of times, it is possible to obtain a solar cell that has excellent contact with measurement probes and has excellent connectivity with tabbing wires.

In the first to third embodiments, the first conductor layer and the second conductor layer are formed from conductive pastes having compositions different from each other; however, the first conductor layer and the second conductor layer may be formed from the same conductive paste.

Note that the configurations described in the above embodiments are examples of the present invention;

combining the present invention with other publicly known techniques is possible, and partial omissions and modifications are possible without departing from the scope of the present invention.

### REFERENCE SIGNS LIST

1 p-type monocrystalline silicon substrate; 4a first conductor layer; 4b second conductor layer; 4G grid electrode; 4B light-receiving-surface bus electrode; Rₐ intra-first-conductor-layer region; R_{b} intra-second-conductor-layer region; R_{Ba} intra-first-back-surface-conductor-layer region, R_{Bb} intra-second-back-surface-conductor-layer region; 6 antireflection film; 7 n-type diffusion layer; 8 BSF layer; 9 back-surface aluminum electrode; 10 back-surface bus electrode; R_{X} overlapping region; 20 lead; 40 first printing plate; 41 second printing plate; 80 holder socket; 81 pin; 82 disk-shaped contact portion; 90 voltmeter; 91 ammeter; P_{A}, P_{B} probe pin; P_{IA}, P_{IB} current terminal of probe pin; P_{VA}, P_{VB} voltage terminal of probe pin; h₁ first opening; h₂ second opening; h₃ third opening.

1. A manufacturing method for a solar cell, wherein
the solar cell includes:
a solar cell substrate; and
first and second collection electrodes formed on the solar cell substrate, at least one of the first and second collection electrodes includes:
grid electrodes formed in a distributed manner over a whole surface of the solar cell substrate; and
a bus electrode that is in contact with the grid electrodes and from which current is drawn, and the method comprises forming a shape pattern of the bus electrode and the grid electrodes by performing a screen printing a plurality of times in such a manner that the bus electrode is divided into a plurality of bus electrodes only in a longitudinal direction and that the divided bus electrodes include an overlapping region only in the longitudinal direction.

2. The manufacturing method for a solar cell according to claim 1, wherein
the screen printing comprises:
printing a first conductive paste in part of a region that is to be the bus electrodes and forming a first conductor layer by using a first printing plate having a first opening that includes a discontinuous portion extending in the longitudinal direction; and
printing a second conductive paste and forming a second conductor layer by using a second printing plate having a second opening partially overlapping with the first opening and a third opening corresponding to the grid electrodes, and
the bus electrodes have an overlapping region in which the first conductor layer and the second conductor layer partially overlap with each other in the longitudinal direction.

3. The manufacturing method for a solar cell according to claim 2, wherein the first conductive paste and the second conductive paste have compositions different from each other.

4. The manufacturing method for a solar cell according to claim 2, wherein the forming the second conductor layer is performed after the forming the first conductor layer.

5. The manufacturing method for a solar cell according to claim 2, wherein the forming the first conductor layer is performed after the forming the second conductor layer.

6. The manufacturing method for a solar cell according to claim 2, wherein
a divided shape pattern of the bus electrodes and the grid electrodes includes:
a second divided shape pattern that is obtained by using the second printing plate and that includes the grid electrodes and a portion in which the bus electrodes and a lead are mechanically held down in a process of connecting the lead to the bus electrodes; and
a first divided shape pattern that is obtained by using the first printing plate and that includes a remaining bus electrode.

7. The manufacturing method for a solar cell according to claim 2, wherein
a divided shape pattern of the bus electrodes and the grid electrodes includes:
a third divided shape pattern that is obtained by using the second printing plate and that includes the grid electrodes and the bus electrodes that include both of a portion in which the bus electrodes and a lead are mechanically held down in a process of connecting the lead to the bus electrodes and a portion into which a probe pin comes into contact when an output of the solar cell is measured; and
a fourth divided shape pattern that is obtained by using the first printing plate and that includes part of the bus electrodes.

8. The manufacturing method for a solar cell according to claim 3, wherein the first conductor layer has a lower silver content than the second conductor layer.

9. A solar cell comprising:
a solar cell substrate; and
first and second collection electrodes formed on the solar cell substrate, wherein
at least one of the first and second collection electrodes includes a collection electrode,
the collection electrode includes:
grid electrodes formed in a distributed manner over a whole surface; and
a bus electrode that is in contact with the grid electrodes and from which current is drawn,
the bus electrode includes:
a first conductor layer that includes a discontinuous portion extending in a longitudinal direction; and
a second conductor layer that includes a portion overlapping with the first conductor layer and covers the discontinuous portion, and
the grid electrodes are formed from the first conductor layer or the second conductor layer.

10. The solar cell according to claim 9, wherein the first conductor layer and the second conductor layer have compositions different from each other.

11. The solar cell according to claim 9, wherein
the grid electrodes are formed from the second conductor layer, and
the bus electrode has, in a portion in the longitudinal direction, an overlapping region in which the second conductor layer is superimposed on the first conductor layer.

12. The solar cell according to claim 9, wherein
the grid electrodes are formed from the second conductor layer, and
the bus electrode has, in a portion in the longitudinal direction, an overlapping region in which the first conductor layer is superimposed on the second conductor layer.

13. The solar cell according to claim 9, wherein
a divided shape pattern of the bus electrode and the grid electrodes includes:
a first divided shape pattern that includes divided bus electrodes located at six to eight locations and the grid electrodes; and
a second divided shape pattern that includes a remaining bus electrode.

14. The manufacturing method for a solar cell according to claim 4, wherein the first conductor layer has a lower silver content than the second conductor layer.

15. The manufacturing method for a solar cell according to claim 5, wherein the first conductor layer has a lower silver content than the second conductor layer.

16. The manufacturing method for a solar cell according to claim 6, wherein the first conductor layer has a lower silver content than the second conductor layer.

17. The manufacturing method for a solar cell according to claim 7, wherein the first conductor layer has a lower silver content than the second conductor layer.
